(19) United States
(12) Patent Application Publication
(10) Pub. No.: US 2020/0162084 A1
(43) Pub. Date: May 21, 2020

(54) FBAR-BASED LOCAL OSCILLATOR GENERATION

(71) Applicant: Avago Technologies International Sales Pte. Limited, Singapore (SG)

(72) Inventors: Hooman DARABI, Irvine, CA (US); David MURPHY, Irvine, CA (US); Arya BEHZAD, San Jose, CA (US); Dihang YANG, Irvine, CA (US); Hung-Ming CHIEN, Irvine, CA (US); Choong Yul CHA, Irvine, CA (US)

(21) Appl. No.: 16/681,526

(22) Filed: Nov. 12, 2019

Related U.S. Application Data
(60) Provisional application No. 62/768,695, filed on Nov. 16, 2018.

(51) Int. Cl. H03L 7/23; H03L 7/099; H03B 5/12; H03B 5/30; H03H 9/02; H03H 9/17

(52) U.S. Cl. CPC H03L 7/235; H03L 7/099; H03H 9/171; H03B 5/30; H03H 9/02007; H03B 5/1271

(57) ABSTRACT

In some aspects, the disclosure is directed to methods and systems for utilizing a thin-film bulk acoustic resonator (FBAR) as a frequency reference for a phase-locked loop (PLL) circuit controlling frequency of a voltage controlled oscillator (VCO). In some implementations, the FBAR-based oscillator may be used as a reference to an analog or digital PLL circuit (either directly, or divided to a lower frequency). In other implementations, the FBAR-based oscillator may be used as a reference to a mixing-based PLL rather than a dividing-based PLL. Through these implementations, the noise contribution of many of the PLL circuit components or elements may be reduced (e.g. noise from a delta-sigma modulator (DSM), multiple modulus divider (MMD), phase frequency detector (PFD)/charge pump (CP), etc.).

### RELATED APPLICATIONS

The present application claims the benefit of and priority to U.S. Provisional Patent Application No. 62/768,695, entitled “FBAR-Based Local Oscillator Generation,” filed Nov. 16, 2018, the entirety of which is incorporated by reference herein.

### FIELD OF THE DISCLOSURE

This disclosure generally relates to systems and methods for wireless communications. In particular, this disclosure relates to systems and methods for using a thin film bulk acoustic resonator-based oscillator for generation of reference signals for wireless communications.

### BACKGROUND OF THE DISCLOSURE

Wireless receivers and transmitters frequently use locally generated reference signals, sometimes referred to as a local oscillator (LO) signal, for tuning to and filtering of received signals or for generation of carrier frequencies for transmitters. In many implementations, silicon crystal-based oscillators (XO) are utilized as an initial reference for a phase-locked loop (PLL) control system to generate a stable carrier or reference frequency. The XO oscillator may frequently operate in the MHz range, while the PLL output may be significantly higher, e.g. in the GHz range. As part of the control system, the PLL output may be divided down and compared to the XO reference signal. However, this division may result in significant amplification of noise generated by the PLL circuit. This noise may have adverse effects on the circuit, including extending time for oscillator stabilization, increasing power consumption and heat generation, placing limiting requirements on other components (e.g. to reduce overall noise), and potentially limiting the bandwidth capability of the receiver or transmitter.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is an illustration of an implementation of an XO-based phase locked loop (PLL) circuit with a block diagram of structural components, a block diagram illustrating the functional components that contribute to the signal output, and a graph of the corresponding transfer functions;

FIG. 2 is an illustration of an implementation of an FBAR mixing-based oscillator with a block diagram of structural components, a block diagram illustrating the functional components that contribute to the signal output, and a graph of the corresponding transfer functions;

FIGS. 3A-3B are illustrations of another implementation of an FBAR mixing-based oscillator with a block diagram of structural components, a block diagram illustrating the functional components that contribute to the signal output, and a graph of the corresponding transfer functions;

FIG. 3C is an illustration of another implementation of an FBAR-based circuit with a block diagram of structural components and a block diagram illustrating the functional components that contribute to the signal output.

FIGS. 4A and 4B are block diagrams comparing implementations of XO-based PLL and FBAR-based PLL circuits, respectively;

FIG. 5 is a block diagram of an implementation of an FBAR mixing-based oscillator with a digital PLL circuit;

FIG. 6 is a block diagram of an implementation of an FBAR-based oscillator used as a direct reference for an analog or digital PLL circuit;

FIG. 7A is a block diagram of an implementation of an FBAR-based oscillator used as a divided reference for an analog or digital PLL circuit;

FIG. 7B is a block diagram of an implementation of an FBAR-based PLL circuit with integrated self-calibration;

FIGS. 7C and 7D are block diagrams of implementations of an FBAR-based PLL circuit with temperature compensation;

FIG. 7E is a block diagram of an implementation of an adaptive gain control circuit for the implementation of FIG. 7D;

FIGS. 8 and 9 are block diagrams of implementations of FBAR-based PLL circuits with integrated frequency drift compensation;

FIG. 10 is a block diagram of an implementation of a system for direct correction of FBAR drift;

FIGS. 11A-11C are block diagrams of implementations of a system for quantization noise reduction in PLL circuits;

FIG. 11D is a block diagram of an implementation of a notch filter for the implementation of FIG. 11C;

FIG. 12A is a block diagram depicting an embodiment of a network environment including one or more access points in communication with one or more devices or stations; and

FIGS. 12B and 12C are block diagrams depicting embodiments of computing devices useful in connection with the methods and systems described herein.

The details of various embodiments of the methods and systems are set forth in the accompanying drawings and the description below.

### DETAILED DESCRIPTION

The following IEEE standard(s), including any draft versions of such standard(s), are hereby incorporated herein by reference in their entirety and are made part of the present disclosure for all purposes: IEEE P802.11n™; and IEEE P802.11ac™. Although this disclosure may reference aspects of these standard(s), the disclosure is in no way limited by these standard(s).

For purposes of reading the description of the various embodiments below, the following descriptions of the sections of the specification and their respective contents may be helpful:
Section A describes embodiments of systems and methods for thin film bulk acoustic resonator (FBAR)-based local oscillator (LO) generation; and
Section B describes a network environment and computing environment which may be useful for practicing embodiments described herein.

### A. FBAR-Based LO Generation

Wireless receivers and transmitters frequently use locally generated reference signals, sometimes referred to as a local oscillator (LO) signal, for tuning to and filtering of received signals or for generation of carrier frequencies for transmitters. These transmitters and receivers may be used for a variety of communications protocols and systems, including 802.11 (WiFi) communications, cellular communications, Bluetooth communications, near field communications (NFC), satellite communications, or any other type and form of wireless communications.

In many implementations, silicon crystal-based oscillators (XO) are utilized as an initial reference for a phase-locked loop (PLL) control system to generate a stable carrier or reference frequency. The XO oscillator may frequently operate in the MHz range, while the PLL output may be significantly higher, e.g. in the GHz range. As part of the control system, the PLL output may be divided down and compared to the XO reference signal. However, this division may result in significant amplification of noise generated by the PLL circuit. This noise may have adverse effects on the circuit, including extending time for oscillator stabilization, increasing power consumption and heat generation, placing limiting requirements on other components (e.g. to reduce overall noise), and potentially limiting the bandwidth capability of the receiver or transmitter.

Instead, implementations of the systems and methods discussed herein utilize a thin-film bulk acoustic resonator (FBAR) as a reference rather than the crystal oscillator. In some implementations, the FBAR-based oscillator may be used as a reference to an analog or digital PLL circuit (either directly, or divided to a lower frequency). In other implementations, the FBAR-based oscillator may be used as a reference to a mixing-based PLL rather than a dividing-based PLL. While dividing-based PLLs divide down a voltage controlled oscillator (VCO) output before comparing it to a relatively low frequency reference (which may be an XO or FBAR based reference, in various implementations), a mixing PLL down-converts the VCO output by mixing it with the high frequency reference (e.g. FBAR-based reference). By using mixing rather than division in such implementations, the noise contribution of many of the PLL circuit components or elements may be reduced (e.g. noise from a delta-sigma modulator (DSM), multiple modulus divider (MMD), phase frequency detector (PFD)/charge pump (CP), etc.).

FBAR-based oscillators have comparable figures of merit (a benchmark of performance of the oscillator, sometimes referred to as FOM, and which may be equal to the phase noise of the oscillator at an offset frequency f_{offset} from its resonant frequency f_{osc}, minus 10 log (f_{osc}/f_{offset})̂2, plus 10 log (P_{DC}/1 mW), where P_{DC} is the power consumption of the oscillator, sometimes expressed in dBc/Hz) to crystal based oscillators, and have a comparably limited tuning range to crystal based oscillators. However, unlike crystal based oscillators which may operate in the MHz range as noted above, FBAR-based oscillators may operate in the GHz range, reducing or eliminating the need for a fractional divider in the PLL circuit and correspondingly reducing or eliminating quantization noise. This may reduce time for oscillator stabilization, and reduce power consumption and heat generation by the circuit. In many implementations, design requirements for other components in the circuit may be reduced due to the reduced PLL noise, reducing costs and simplifying design and manufacture. In some implementations, the bandwidth capability of the receiver or transmitter may be expanded as a result.

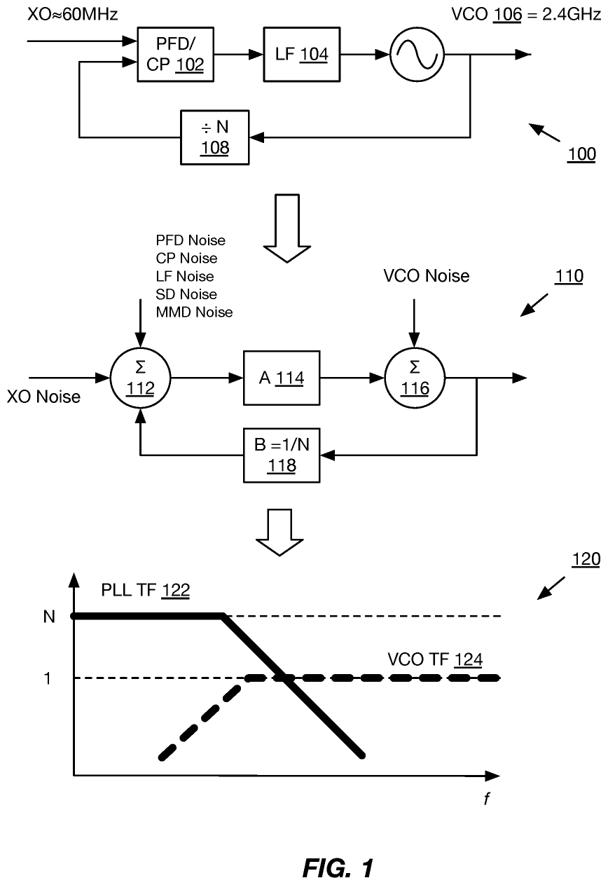

Referring first to FIG. 1, illustrated is an implementation of an XO-based phase locked loop circuit with, from top to bottom, a block diagram of structural components 100, a block diagram illustrating the functional components that contribute to the signal output 110, and a graph of the corresponding transfer functions 120. Referring first to the block diagram of structure components 100, in many implementations, an XO-based PLL circuit may comprise a PFD/CP 102 that receives an input reference signal from a crystal oscillator (e.g. at 60 MHz) and provides an output error signal proportional to a phase difference between the reference signal and a feedback signal to the charge pump. The error signal is filtered by loop filter 104 (e.g., a low pass filter), and provided to a VCO 106, which generates an output signal at high frequency (e.g. 2.4 GHz). The output signal is fed back to a decimator or divider 108 to reduce the output to the reference signal frequency. The divided signal is provided to the PFD/CP 102 to adjust the error signal relative to the reference signal from the XO, providing a negative feedback loop.

As shown in the functional diagram 110, the output signal is a sum 112 of various noise signals including XO noise, PFD noise, CP noise, LF noise, and sigma-delta (SD) and multiple modulus divider (MMD) noise (if included in the PLL circuit), and VCO noise 116, and proportional to the VCO and divider signals 114, 118. In some implementations using the architecture illustrated, the transfer function 122 for the PLL is equal to (A/(1+AB))+(1/B)+N, with N being the PLL noise components amplified by N. In typical implementations using frequency multiplication by N, the resulting noise signal is amplified by 20 Log(N) dB. This may be significantly higher in amplitude at lower frequencies than the VCO transfer function 124, restricting the useable bandwidth, and potentially restricting channel spacing.

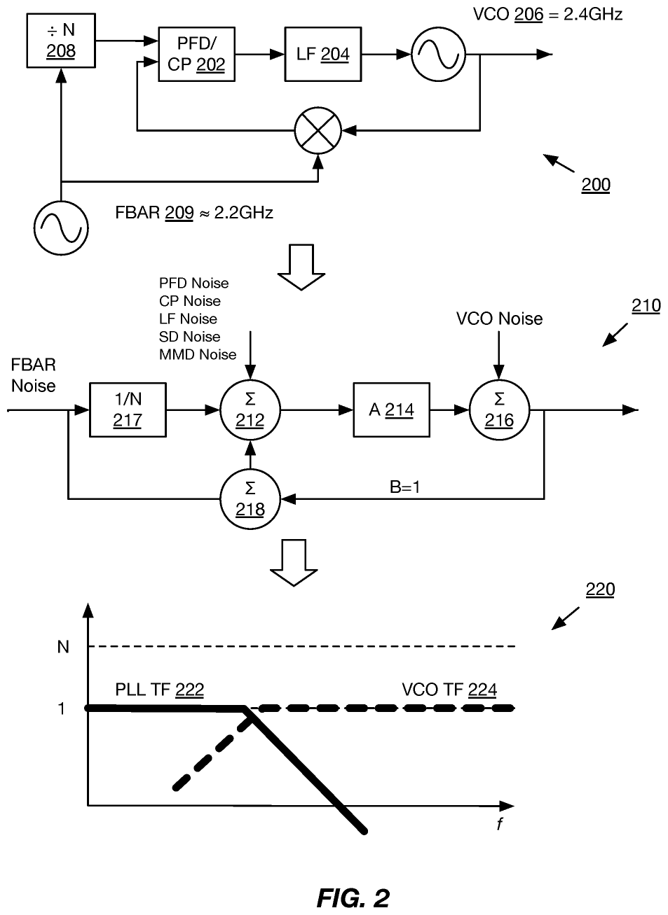

FIG. 2 is an illustration of an implementation of an FBAR mixing-based oscillator with a block diagram of structural components 200, a block diagram illustrating the functional components that contribute to the signal output 210, and a graph of the corresponding transfer functions 220. An FBAR-based oscillator 209 provides a reference signal at a frequency close to or corresponding to the VCO output frequency 206. The reference signal may be reduced in frequency via divider 208, and provided to PFD/CP 202. In some implementations, the comparison signal may comprise a mix of the VCO output signal 206 and FBAR-based reference signal 209. Mixing the two signals results in an intermodulation product at a lower frequency for use by the PFD/CP, without the divider being part of the feedback path, and as a result, the noise contribution of the PLL circuit blocks may be significantly reduced. For example, as shown in the functional diagram 210 and unlike the implementation of FIG. 1, the modulus parameter B is equal to 1. The noise signals are summed as part of the transfer function as before (e.g. 212, 216, 218), but due to divider 217 not contributing to B, the resulting transfer function PLL TF 222 is equal to (A/(1+AB))+(1/B)+1. As a result, the steady state value of the VCO TF is not adversely affected by the PLL noise, expanding the useable bandwidth, and also reducing system power and heating. In some implementations, additional filtering (active or passive) may be applied after the mixer to further minimize noise. In some further implementations, narrow-band PLL, delay-locked loop (DLL), or injected locked oscillator circuitry may be used to achieve a filtering effect.

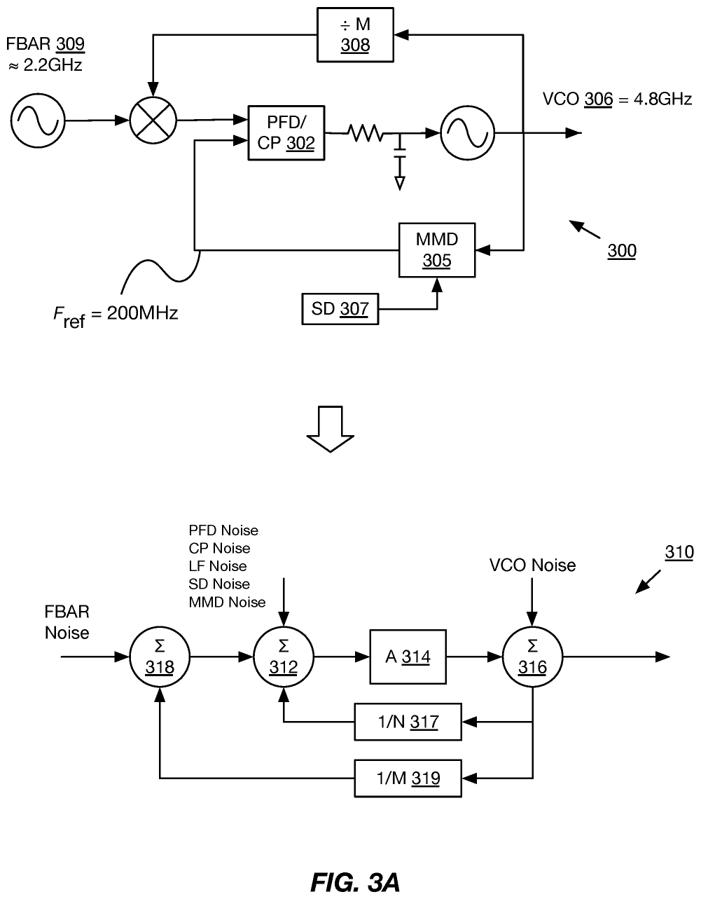

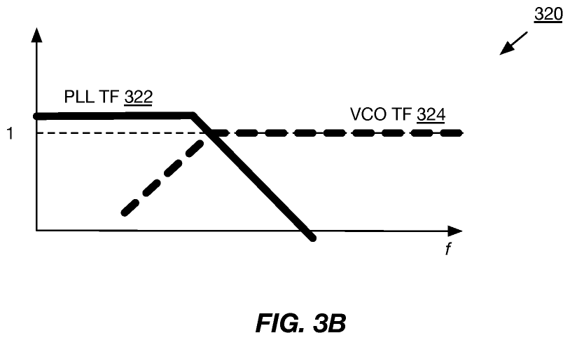

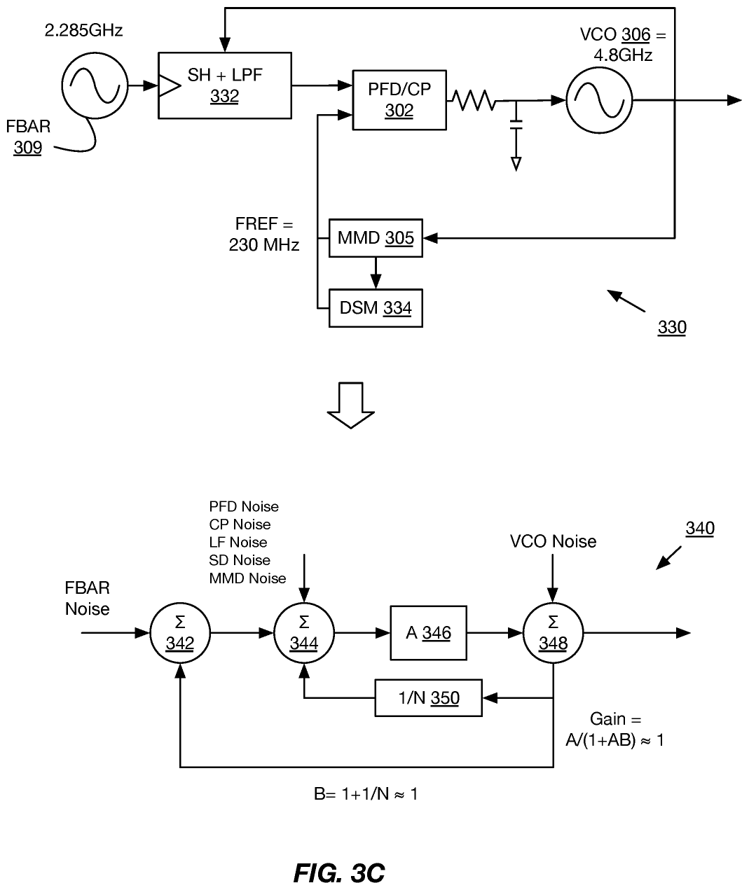

In a similar implementation illustrated in FIGS. 3A-3B, an SD 307/MMD 305 circuit may be included as part of one feedback path to PFD/CP 302 from VCO output 306 to provide a lower frequency F_{ref} signal. The FBAR reference signal 309 may be mixed with a frequency reduced version of the VCO signal via divider 308. This may be particularly useful in implementations in which the oscillation frequency of the VCO is much greater than the FBAR frequency (e.g. 4.8 GHz compared to 2.2 GHz as illustrated). For example, given F_{ref} of 200 MHz as shown and an M modulus of 2, the VCO signal may be reduced from 4.8 GHz to 2.4 GHz and mixed with the FBAR signal of 2.2 GHz to generate a corresponding 200 MHz intermodulation product for PFD/CP 302. In the implementation illustrated in the structural block diagram 300 of FIG. 3A, a passive low pass filter is utilized after PFD/CP 302 as a loop filter, though other filter implementations are possible.

As shown in the functional block diagram 310, the decimated feedback signals 317, 319 are summed with noise signals (e.g. 312, 316, 318) and amplified (A 314), and the resulting transfer function is illustrated in the graph of FIG. 3B, with PLL TF 322 equal to (A/(1+AB))+(1/B)+(1/(M+N))+M, with M being an integer value greater than or equal to 1. Though allowing some greater noise levels than the implementation of FIG. 2, the implementation of FIGS. 3A-3B may accommodate VCO frequencies much higher than the FBAR frequency. In some implementations, the SD/DSM noise may be filtered at the MMD output via an active filter, passive filter, PLL, or DLL to further reduce noise and minimize degradation of performance of the PLL through excitation of nonlinearities in the PFD/CP or down-conversion of high frequency SD/DSM noise.

FIG. 3C is an illustration of another implementation of an FBAR-based circuit 330 with a block diagram of structural components and a block diagram illustrating the functional components 340 that contribute to the signal output, in which the mixer of FIGS. 3A-3B has been replaced with a sample and hold circuit (SH) and a low pass filter (LPF) 332. The SH and LPF downconverts the output of VCO 306 using a 2^{nd} harmonic component of the FBAR oscillator output signal, with the result provided as an input to PFD/CP 302. The resulting functional diagram illustrates summing 342 of FBAR noise with a feedback signal B, approximately equal to 1, with the result summed 344 with other noise sources and a feedback signal of 1/N via divider 350. Amplifier 346 provides gain of A from the summed signal, which is added 348 to VCO noise, and the resulting transfer function for the circuit is A/(1+AB), approximately equal to 1, thus showing that MMD noise in circuit 330 is not amplified.

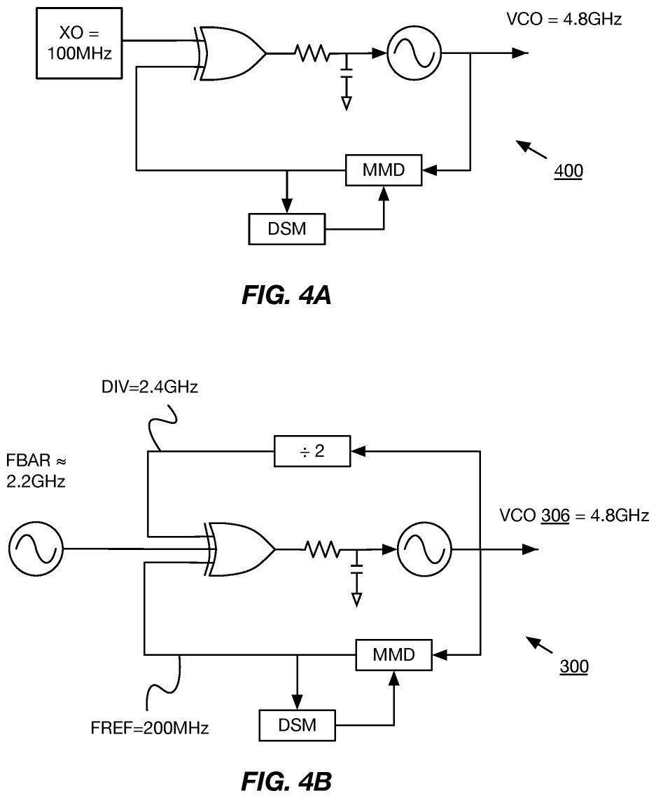

FIGS. 4A and 4B are block diagrams comparing implementations of XO-based PLL and FBAR-based PLL circuits, respectively. Referring first to the implementation illustrated in FIG. 4A, an XOR circuit is used as a phase detector comparing an input from XO and a feedback loop provided via the DSM and MMD. By comparison, and referring to the implementation illustrated in FIG. 4B utilizing an FBAR oscillator as a reference, a divider may be utilized as part of a feedback loop to reduce a VCO signal to a frequency similar to the FBAR frequency.

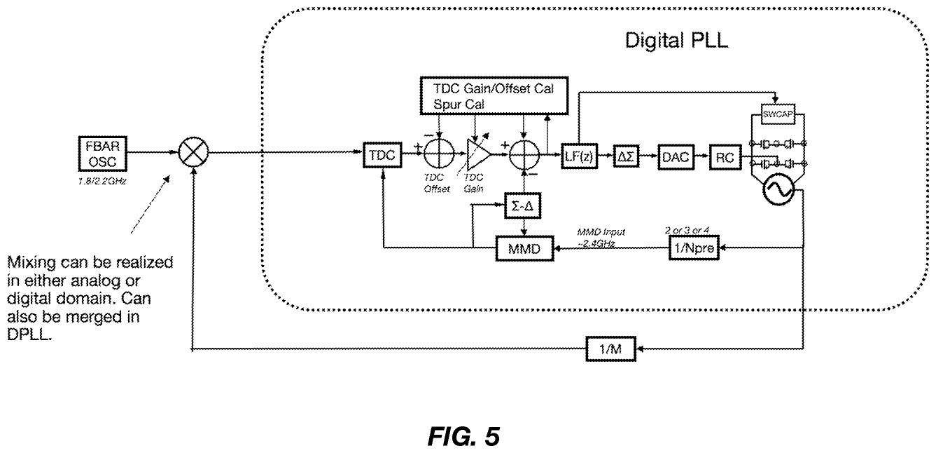

The implementation of FIG. 4B is similar to the implementations of a type-I PLL illustrated in FIGS. 3A-3B; however, similar implementations may also be used with analog type-II PLLs, digital PLLs, etc. For example, FIG. 5 is a block diagram of an implementation of an FBAR mixing-based oscillator with a digital PLL circuit. The implementation shown is similar to the implementation of FIG. 3A, but utilizing a digital PLL in place of PFD/CP 302 and the passive loop filter. In some implementations, as shown, an FBAR-based oscillator signal at a first frequency may be mixed with a divided output of a VCO, and provided to a time-to-digital converter (TDC). The mixing may be performed in either the analog or digital domain, depending on implementation. Use of the digital PLL with the FBAR mixing-based oscillator circuit may enable efficient quantization noise cancellation and spur cancellation techniques.

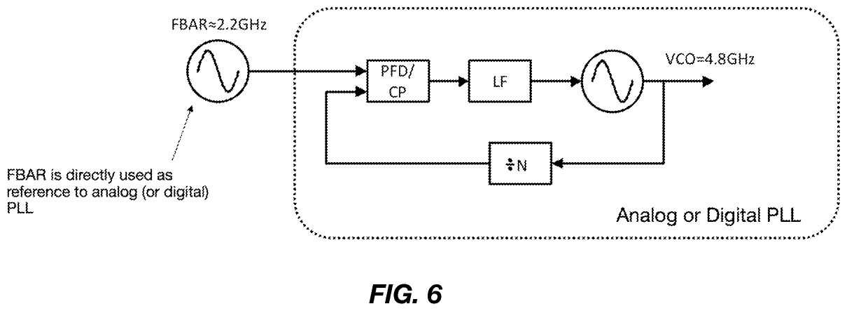

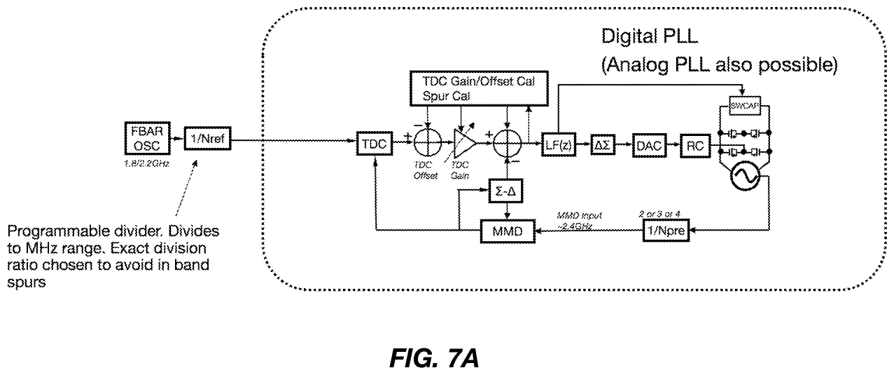

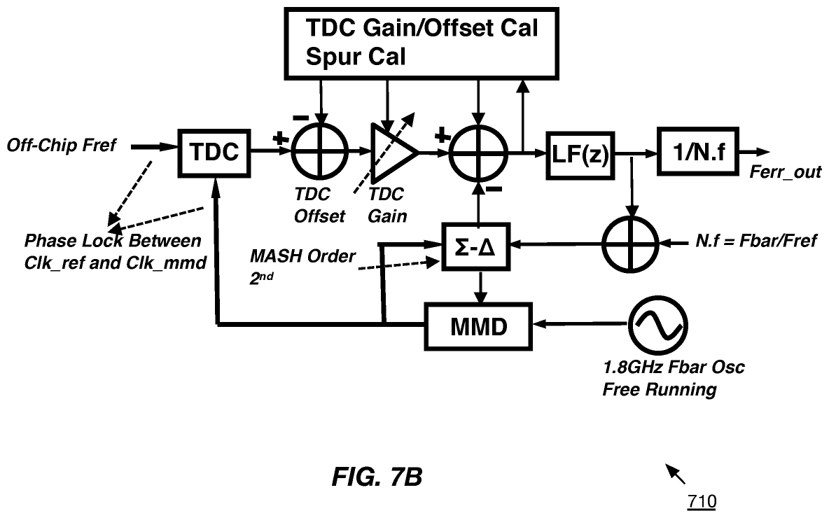

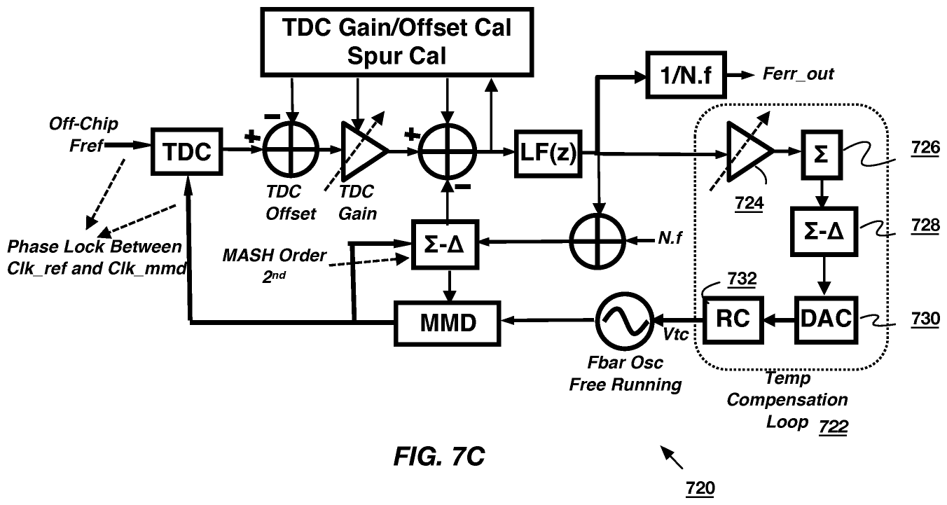

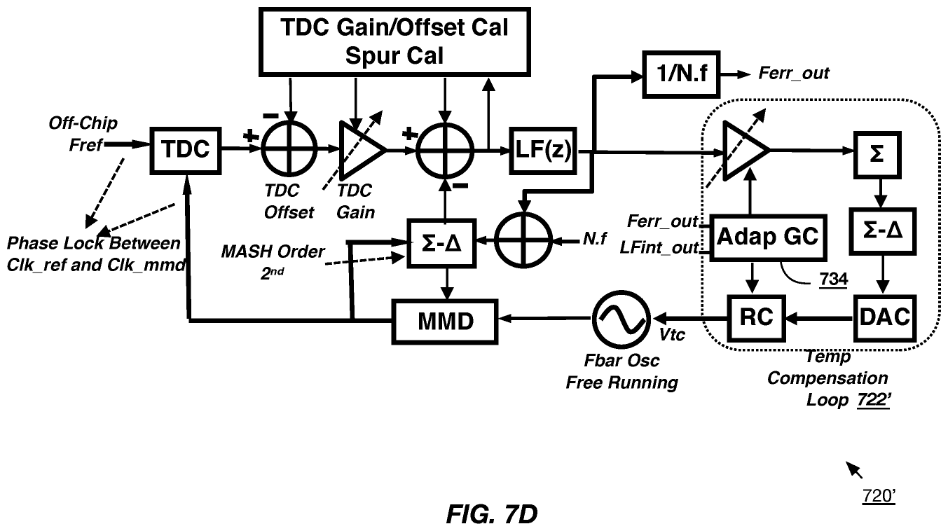

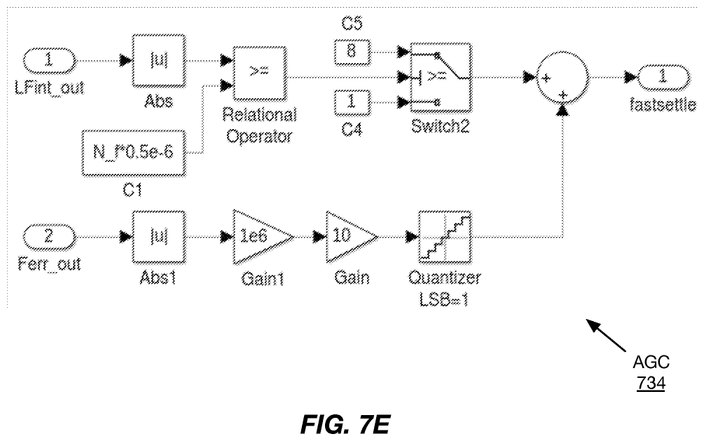

In another aspect, the FBAR oscillator-based systems and methods discussed herein may also be used with non-mixing PLL implementations, either directly as a reference signal to an analog or digital PLL as shown in the example implementation of FIG. 6, or by dividing the FBAR generated reference signal to generate a low frequency signal for an input to an analog or digital PLL, as shown in the example implementation of FIG. 7A. In implementations utilizing the FBAR oscillator signal as a direct reference signal, the components of the PLL (e.g. CP, MMD, DSM, or digital equivalents) may be configured to operate at the FBAR frequency (e.g. in the GHz range, for many implementations), which may have greater PLL noise suppression. In implementations dividing the FBAR reference signal, the PLL components may operate at a lower frequency (e.g. in the MHz range for many implementations), which may be more power efficient and easier to manufacture.

FIG. 7B is a block diagram of an implementation of an FBAR-based PLL circuit 710 with integrated self-calibration. As shown, the circuit is simpler and requires fewer components and less filtering, saving manufacturing costs and power consumption in the device. In the implementation of FIG. 7B, a free running FBAR oscillator drives an MMD circuit. A loop filter (LF) provides an output that modulates a feedback divide ratio (N.f) of the FBAR oscillator frequency divided by a reference oscillator frequency (e.g. from a crystal oscillator or other stable source). The phase lock is formed at the Time to Digital Converter (TDC) inputs between the reference oscillator and the divided FBAR oscillator (e.g. output from MMD). Dividing the loop filter output by N.f provides a measure of a normalized frequency error (F_{err_out}). Accordingly, the circuit provides:

$${Fmmd}_{out} = Fref = \frac{Fbar}{( N . f + {LF}_{out} )}$$

In testing implementations, the PLL locked within 25 μs, with a lock bandwidth of approximately 900 KHz. The error rate F_{err_out} settled within 200 μs to under 0.1 ppm accuracy. In some implementations, removal of the low pass filter from the circuit path may decrease error settling time.

FBAR calibration with a digital PLL circuit can detect the FBAR oscillator's frequency to within 0.03 ppm in many implementations. The detected frequency error may be used to correct the FBAR oscillator frequency, allowing internal control and correction. In many implementations, a small varactor (sometimes referred to as a varactor diode or varicap) may be used to tune the FBAR oscillator frequency without significantly degrading its phase noise. The required tuning range is relatively small, and is based on the FBAR oscillator's temperature variation range in many implementations (e.g. 200-300 ppm). Advantageously, the temperature compensated FBAR oscillator does not generate temperature-dependent spur content in its output due to frequency drift, and by compensating for temperature changes, there's no need to trim other PLL circuits on the chip using the FBAR oscillator as a reference.

FIGS. 7C and 7D are block diagrams of implementations of an FBAR-based PLL circuit with temperature compensation. Referring first to FIG. 7C, the circuit 720 is similar to implementations of the FBAR-based PLL circuit 710 of FIG. 7B, with the addition of temperature compensation loop 722. Rather than detecting an error or drift in the frequency of the FBAR oscillator and sending the error to another PLL circuit for trimming, the temperature compensation loop may be used to control the FBAR oscillator's frequency directly to correct for drift.

As shown, the loop filter output (LF(z)) may represent the FBAR oscillator's frequency error. This output may be provided to a gain controller 724 of temperature compensation loop 722 for control of the temperature compensation circuit's speed and stability (e.g. reducing the gain to slow the adjustment rate). The output of the gain controller 724 is provided to an integrator 726 and sigma-delta modulator 728, which may generate an output that will move up or down responsive to a frequency error. In some implementations, the sigma-delta modulator may comprise a 2^{nd} order modulator, while in other implementations, first-order or higher order modulators may be used. The comparator output may be converted from a digital output to analog via DAC converter 730, and an RC filter 732 (or low pass filter, in some implementations) may be used filter the analog signal to provide a control voltage Vtc for the FBAR oscillator. The control voltage Vtc will move up or down to correct the oscillator frequency until the detected error (LF(z) output) is zero. In some implementations, the digital-to-analog conversion may be skipped, and the sigma-delta output may be used to digitally control a capacitor bank in the FBAR oscillator (e.g. as cap codes or other serial or parallel control signals).

FIG. 7D shows another implementation of an FBAR-based PLL circuit 720′ with temperature compensation 722′ with adaptive gain control 734. In many implementations, the temperature control loop 722 may take some time to settle when adjusting for drift. For example, as discussed above in connection with FIG. 7C, if gain controller 724 is set too high, the temperature compensation loop and frequency adjustment of the FBAR oscillator may be unstable. Conversely, setting the gain control lower will increase stability, but reduce response rate and slow the adjustment process. This may result in some time taken before the oscillator frequency is adjusted and drift is compensated for, which may result in lost transmissions, dropped packets, etc. Accordingly, in some implementations, an adaptive gain control 734 may be used to dynamically adjust gain of gain controller 724 to increase gain initially when compensating for drift, and then reduce gain when the error measurement is small. In some implementations, adaptive gain controller 734 may also adjust bandwidth of filter 732, further accelerating compensation and settling time. For example, to compensate for frequency errors initially, the gain of gain controller 724 may be set to a high level and the filter bandwidth may be set to a wide bandwidth value; as the error is reduced, the gain may be reduced to a lower level and the filter bandwidth may be reduced to a narrower bandwidth value.

The adaptive gain controller 734 may be controlled via the loop filter output (LF_{int_out}) and output frequency error (F_{err_out}). When there's a phase or frequency disturbance, the loop filter output may respond faster, but may be noisier, while the output frequency error may respond slower with less noise. In some implementations, if the loop filter output is greater than a threshold (e.g. 0.5 ppm), then gain of the gain controller may be increased by a predetermined amount (e.g. 8 times the input signal, though other gain levels may be used). Similarly, in some implementations, if the output frequency error is above a threshold (e.g. 0.1ppm), then the gain may be increased proportionally to the error (e.g. round(F_{err_out}/0.1ppm)).

FIG. 7E is a block diagram of an implementation of an adaptive gain control circuit 734for the implementation of FIG. 7D. Each input signals (LF_{int_out} and F_{err_out}) may be converted to an absolute value. The LF_{int_out} signal may be compared to a threshold (coefficient C1), and responsive to the comparison, a gain level selected (e.g. unity gain of 1, coefficient C4; or gain of 8 times, coefficient C5) and provided to the gain controller. Similarly, the F_{err_out} signal may be amplified and quantized, with the result provided to the gain controller. A fast settle signal may be output to trigger the gain controller to read a new gain value from a shared memory buffer or bus, as well as to control bandwidth of the filter 732, in some implementations. Accordingly, the use of the adaptive gain control in the temperature compensation loop may significantly increase speed of frequency settling of the FBAR oscillator, achieving settling back to 0.02 ppm within around 15 μs, in tests, starting from a 5 ppm frequency jump.

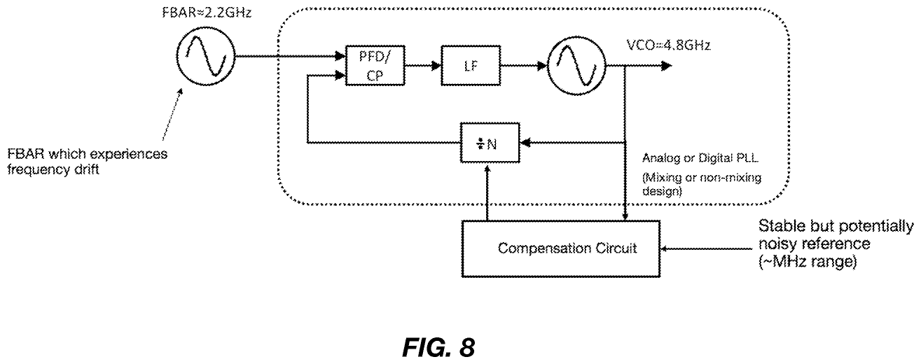

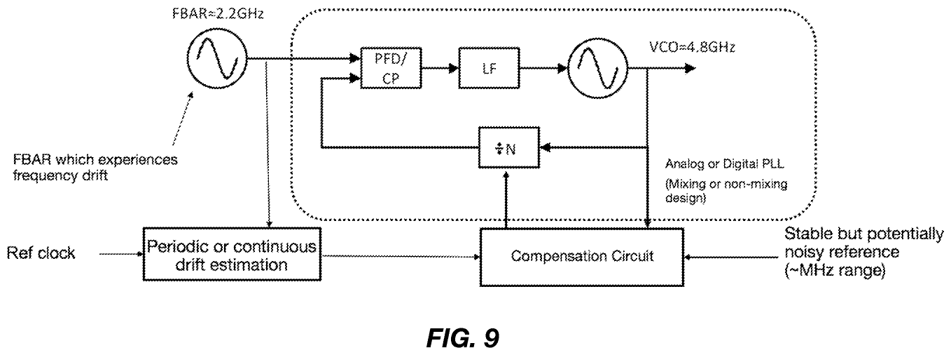

In some implementations, FBAR-based oscillators may be prone to frequency drift due to manufacturing variation, packaging stress, environmental effects such as temperature or humidity, aging, etc. The frequency drift may be very slow with respect to the oscillation frequency in many implementations, but may be quite large (e.g. on the order of 1200 ppm). In some implementations, this drift may be compensated for by changing the division ratio in the PLL. For example, FIG. 8 is a block diagram of an implementation of an FBAR-based PLL circuit with integrated frequency drift compensation. The compensation circuit may utilize a second clock reference that is more stable than the FBAR oscillator, such as an XO or another clock reference, typically at a lower frequency (e.g. in the MHz range). In many implementations, although stable, this second clock reference may not be directly used as a reference for the PLL circuit because of increased noise and/or poor spectral purity. However, it may be used as a clock reference to compensate for FBAR drift. FIG. 9 is another block diagram of an implementation of an FBAR-based PLL circuit with integrated frequency drift compensation. The reference clock may have high stability (e.g. low ppm frequency drift), and may be based on a local oscillator frequency from wireless packets received from an access point; a high stability clock used for a processor within a device such as a mobile or portable computing device or smartphone; a clock of an interface processor such as a PCIe or SerDes interface within a device; a low frequency, high stability XO (e.g. a 32 KHz crystal oscillator); or any other stable reference clock. The reference clock may be used to estimate periodic or continuous drift in the FBAR oscillator output, and the modulus of a divider may be adjusted accordingly to ensure that the divided signal causes the PLL to compensate for the drift (e.g. increasing the modulus and thereby further reducing the divided signal, responsive to the FBAR oscillator frequency lowering; or decreasing the modulus and thereby increasing the divided signal, responsive to the FBAR oscillator frequency increasing). Because in normal operations with a stable FBAR frequency, the PLL circuit will cause the VCO frequency to “chase” the FBAR frequency (adjusting the VCO frequency upwards if the VCO frequency is low, or downwards if the VCO frequency is high) based on the difference between the FBAR frequency and divided VCO signal, making an opposing change to the divided signal will compensate for frequency drift in the FBAR oscillator (e.g. if the FBAR frequency lowers, then further reducing the divided VCO signal by increasing the divider modulus will cause the PLL circuit to increase the output frequency; if this adjustment is performed periodically or continuously responsive to changes in the FBAR frequency, then the output frequency may be substantially stable despite FBAR frequency drift).

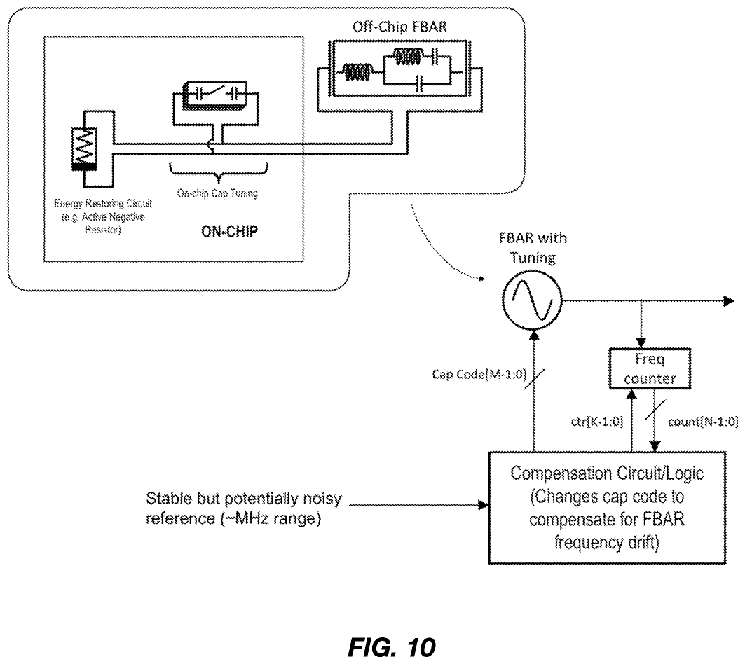

In another implementation, digital compensation logic may be used to directly correct FBAR frequency drift, e.g. by adding capacitive tuning to the FBAR oscillator core and adjusting the frequency based on a reference clock. For example, a reference clock such as those discussed above may have high stability, though low frequency (e.g. a crystal oscillator). FIG. 10 is a block diagram of an implementation of a system for direct correction of FBAR drift. As shown in some implementations, on-chip capacitive tuning such as a capacitor bank may be connected to an FBAR oscillator with capacitor selection chosen by a compensation circuit and communicated via digital controls (e.g. control bits or cap codes). The compensation circuit may receive as inputs a stable reference (e.g. crystal oscillator or other stable reference frequency) and a frequency counter connected to the output of the FBAR oscillator. The frequency may be counted by the counter and via a lookup table or other logic, appropriate capacitance may be selected. Control bits may be transmitted from the compensation circuit to the capacitor bank to enable and/or disable specific capacitors to achieve the desired value. The compensation logic may be embodied in hardware, such as an ASIC or FPGA, and may comprise one or more comparators configured to receive the reference clock signal and frequency counter output and determine a difference. If the difference is greater or lower than predetermined thresholds, the compensation logic may adjust the cap code to select a new capacitance value (e.g. reducing or increasing capacitance, depending on whether the FBAR oscillator frequency is low or high). Advantageously, the compensation logic is fully digital and may be enabled or disabled or suspended as required. For example, in some implementations, calibration may be suspended and the cap codes may be frozen during packet transmission or reception to avoid adjusting carrier frequencies mid-packet or mid-transmission.

Quantization noise may be an issue in some implementations of PLL circuits. For example, a VCO may have significant levels of noise (e.g. phase noise). Increasing the loop bandwidth may help to suppress the VCO noise, but with a fractional-N PLL circuit, such as the one discussed above in connection with FIG. 8, noise is also introduced by the compensation circuit (e.g. quantization noise from a delta-sigma modulator (DSM)), and increasing the loop bandwidth ends up increasing the DSM noise. Thus, there's a tradeoff between VCO noise and DSM noise. Increasing the operational frequency (e.g. with an input reference frequency from a crystal oscillator f_{ref} provided to a reference multiplier M, such that the loop frequency is M*f_{ref}) helps to reduce quantization noise, relaxing the tradeoff, but crystal oscillators may be limited to lower frequencies than desired, in many implementations (e.g. up to 100 MHz or so, while a VCO may be operating at 10 GHz in many implementations). As discussed above, an FBAR oscillator may allow for higher operational frequencies, but is prone to frequency drift due to temperature changes. Similarly, reference multipliers may either be noisy, if RC-based, or may consume large areas on an integrated circuit, if LC-based.

Instead, in some implementations, a multi-phase phase/frequency detector (PFD) may be utilized with a plurality of phases compared to a reference clock. The compensation circuit (e.g. delta-sigma modulator (DSM) and multiple modulus divider (MMD)) may run at several times the reference frequency (e.g. M times, or M*f_{ref}), with the MMD output divided down to the reference frequency using an M-phase divider. All M of the output phases from the divider may be compared to the reference clock via a corresponding plurality M of PFD circuits, with the result integrated. As a result, added noise and size issues of reference multiplier-based implementations are avoided, while achieving identical performance for VCO and DSM noise.

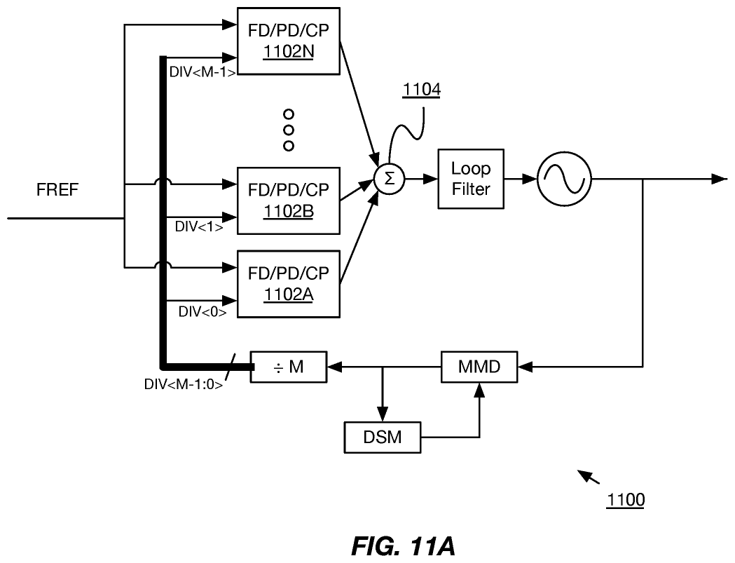

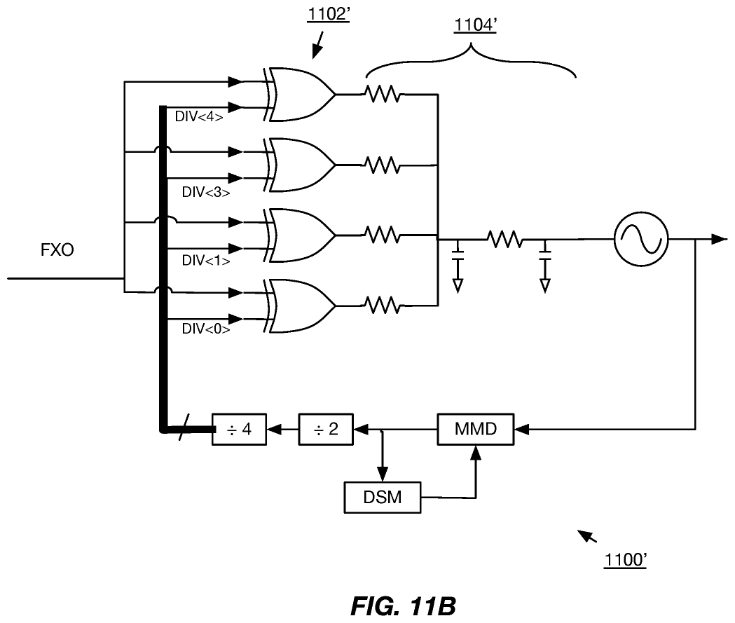

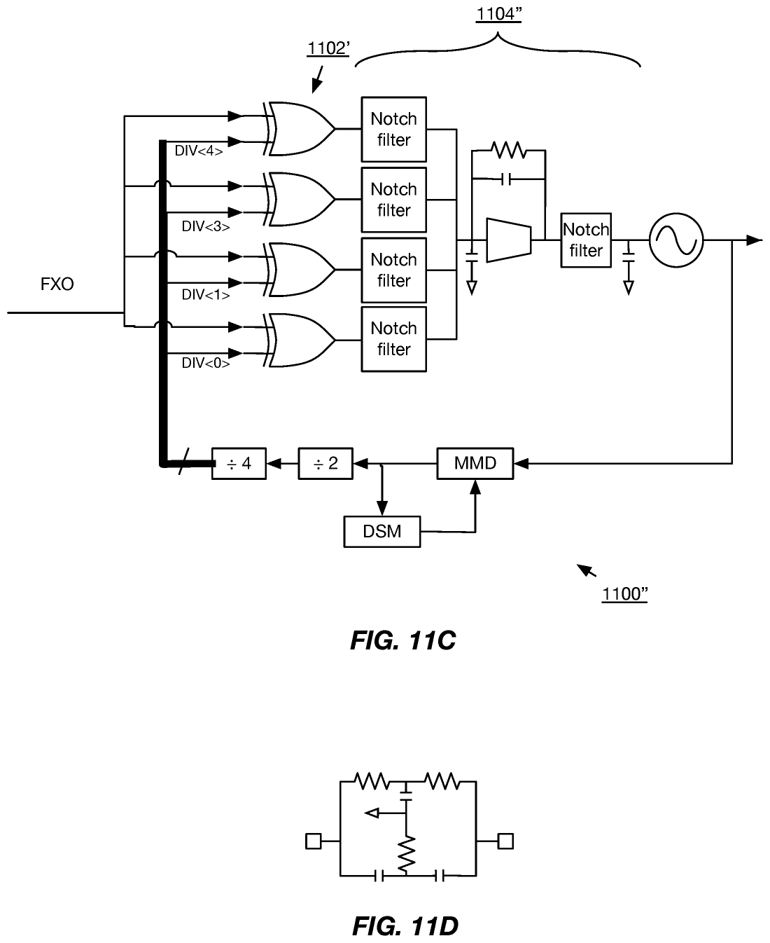

For example, FIG. 11A is a block diagram of an implementation of a system 1100 for quantization noise reduction in PLL circuits. An input reference signal F_{ref} from a reference oscillator (e.g. crystal oscillator or other stable source) may be provided to a plurality n of detectors 1102A-1102N (which may comprise frequency detectors, phase detectors, charge pumps, etc., or a combination of these circuits such as phase detectors and charge pumps). An output oscillator (e.g. FBAR oscillator or other high frequency oscillator) running at M*F_{ref} may be provided to a compensation circuit (e.g. MMD and DSM) and divided by an M-phase divider to be approximately equal to F_{ref}. The M-phase divider may have a plurality M of outputs corresponding to the multiplier of the frequency of the output oscillator relative to F_{ref}, each output providing a different phase. For example, with a 4-phase divider, the outputs may be offset by 180 degrees/4 or 45 degrees each. Each phase-offset divided signal may be provided via a plurality of bus lines to each of the corresponding plurality of detectors 1102A-1102N. The detectors may each compare the input reference frequency to their corresponding phase-offset divided signal to provide an output to combiner 1104. The result may be filtered via a loop filter or other such filter and used to control the output oscillator.

In testing, a 2-phase divider (M=2) reduced 3^{rd} order DSM noise by 15 dB relative to a single-phase divider (e.g. PLL circuit not utilizing a multi-phase divider), without changing the bandwidth. A 4-phase divider (M=4) reduced 3^{rd} order DSM noise by 30 dB relative to the single phase divider.

FIG. 11B is a block diagram of one implementation of a system for quantization noise reduction 1100′. Detectors 1102′ may comprise parallel XOR gates; in the implementation illustrated, a 4-phase divider is used and four phases are provided to the detectors 1102′. In some implementations as shown, an additional divider may be employed in series before the 4-phase divider, allowing for higher output oscillator frequencies without increasing the number of phases and corresponding detectors 1102′. The additional divider may also be useful in implementations in which the output of the MMD is not at a 50% duty cycle, such that the XOR gates may trigger at twice the desired frequency; an alternate implementation utilizing edge-trigger logic (e.g. flip flops) in place of the XOR gates in detectors 1102′ may allow removal of the additional divider. In the implementation illustrated, a 2-pole RC loop filter 1104′ is utilized, with summing of the four detector 1102′ outputs.

FIG. 11C is a block diagram of another implementation of a system for quantization noise reduction 1100″, similar to that of FIG. 11C, but employing an active RC loop filter 1104″ with a plurality of notch filters. Because the PLL bandwidth may be widened in implementations of the system of FIGS. 11A-11C, reference harmonics may otherwise slip through the filter and impair operations of the system (e.g. exciting nonlinearities in the VCO tuning, or appearing in the PLL output signal). Notch filters at one or harmonics of the input reference frequency F_{ref}(e.g. 2*F_{ref}, 4*F_{ref}, etc.) may be included as shown to reduce the effect of these harmonics. FIG. 11D is a block diagram of an implementation of one such passive notch filter although other implementations, including active filters, may be employed.

Although discussed primarily in connection with FBAR-based PLL circuits or other high-frequency reference source, implementations of the multi-phase circuit for quantization noise reduction discussed above may be utilized with any PLL design, including XO-based PLL circuits.

Accordingly, implementations of the systems and methods discussed herein provide for reduced PLL component noise via utilization of an FBAR-based oscillator as a reference rather than a crystal oscillator. In some implementations, the FBAR-based oscillator may be used as a reference to an analog or digital PLL circuit (either directly, or divided to a lower frequency). In other implementations, the FBAR-based oscillator may be used as a reference to a mixing-based PLL rather than a dividing-based PLL. While dividing-based PLLs divide down a voltage controlled oscillator (VCO) output before comparing it to a relatively low frequency reference (which may be an XO or FBAR based reference, in various implementations), a mixing PLL down-converts the VCO output by mixing it with the high frequency reference (e.g. FBAR-based reference). By using mixing rather than division in such implementations, the noise contribution of many of the PLL circuit components or elements may be reduced (e.g. noise from a delta-sigma modulator (DSM), multiple modulus divider (MMD), phase frequency detector (PFD)/charge pump (CP), etc.).

Additionally, either in combination with such implementations or separately, multi-phase division and phase detection may be used to reduce quantization noise in PLL circuits without increasing bandwidth, and without using reference multipliers that may add noise or take up significant amounts of physical space.

In some implementations, the present disclosure is directed to a device, comprising a thin film bulk acoustic resonator (FBAR) circuit; a phase-locked loop (PLL) circuit comprising a voltage controlled oscillator (VCO); and a mixer circuit configured to receive the output signal from the FBAR circuit and an output signal from the VCO, and generate an intermodulation signal; and the PLL circuit is further configured to receive the intermodulation signal as a second input.

In some implementations, the device includes a frequency divider circuit configured to receive an output signal from the VCO and provide a divided signal to the mixer circuit for mixing with the output signal from the FBAR circuit. In some implementations, the frequency divider circuit is an integer divider.

In some implementations, the PLL circuit comprises a multiple modulus divider (MMD) configured to receive the output signal from the VCO. In some implementations, the mixer circuit comprises a sample and hold circuit. In some implementations, the mixer circuit comprises an XOR logic gate. In a further implementation, the XOR logic gate is further configured to receive a frequency divided version of the output signal from the VCO.

In some implementations, the PLL circuit comprises a frequency divider circuit; and the device includes a compensation circuit configured to control a division ratio of the frequency divider circuit, responsive to a detection of frequency drift of the FBAR circuit.

In another aspect, the present disclosure is directed to a temperature compensating phase-locked loop (PLL) circuit. The PLL circuit includes a thin film bulk acoustic resonator (FBAR) circuit; a ring oscillator configured to modulate an output signal from the FBAR circuit and a reference frequency signal; a loop filter configured to receive the modulated output signal and generate a signal representing a frequency error of the FBAR circuit; and a temperature compensation loop circuit, configured to receive the frequency error signal from the loop filter and generate a control signal for the FBAR circuit.

In some implementations, the temperature compensation loop circuit further comprises an amplifier configured to receive the frequency error signal from the loop filter and generate a gain adjusted frequency error signal. In a further implementation, the PLL circuit includes an adaptive gain control circuit configured to monitor the frequency error signal from the loop filter and control gain of the amplifier, responsive to the monitoring. In a still further implementation, the adaptive gain control circuit is configured to increase gain of the amplifier responsive to determining that the frequency error signal exceeds a threshold. In another still further implementation, the temperature compensation loop further includes an adjustable bandwidth filter. In a yet still further implementation, the adaptive gain control circuit is further configured to increase bandwidth of the adjustable bandwidth filter, responsive to determining that the frequency error signal exceeds a threshold.

In another aspect, the present disclosure is directed to a multi-phase phase-locked loop (PLL) circuit comprising: an oscillator; a multi-phase divider receiving an output of the oscillator and comprising a plurality of frequency divided outputs, each frequency divided output of the multi-phase divider having a corresponding phase offset; a corresponding plurality of detectors, each detector receiving a corresponding frequency divided output of the multi-phase divider and an input reference signal and configured to generate a difference signal representative of a difference between the corresponding frequency divided output and the input reference signal; and a combiner in communication with each of the plurality of detectors configured to generate a single combined output of the plurality of generated difference signals, the single combined output controlling a frequency of the oscillator.

In some implementations, the PLL circuit includes a compensation circuit receiving the output of the oscillator and providing a compensated output to the multi-phase divider. In a further implementation, the compensation circuit comprises a delta-sigma modulator in parallel with a multiple modulus divider. In some implementations, each detector comprises an XOR logic gate. In some implementations, each detector comprises an edge-triggered logic circuit. In some implementations, the PLL circuit further includes a plurality of notch filters tuned to a harmonic of the input reference signal, each receiving an output of a corresponding detector of the plurality of detectors.

### B. Computing and Network Environment

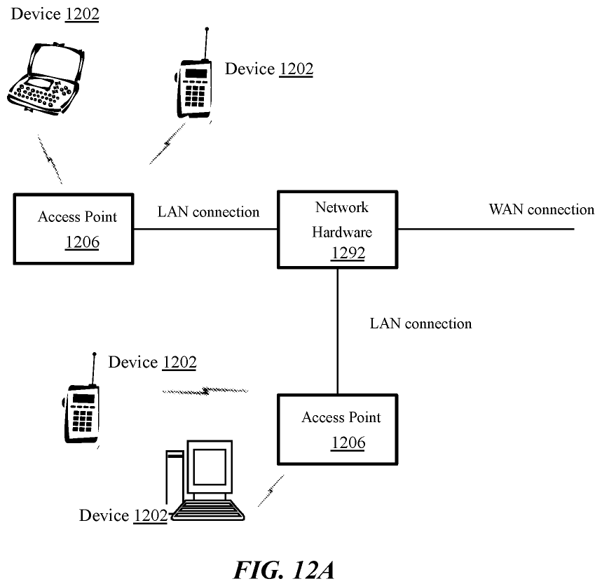

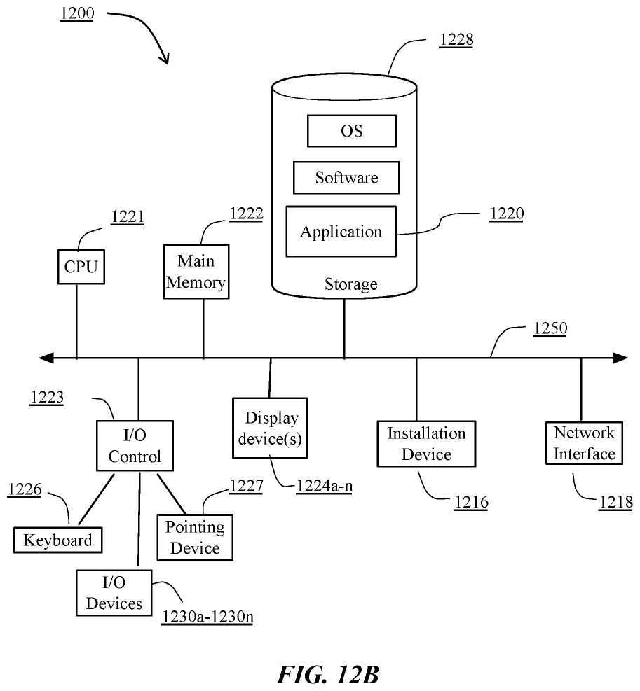

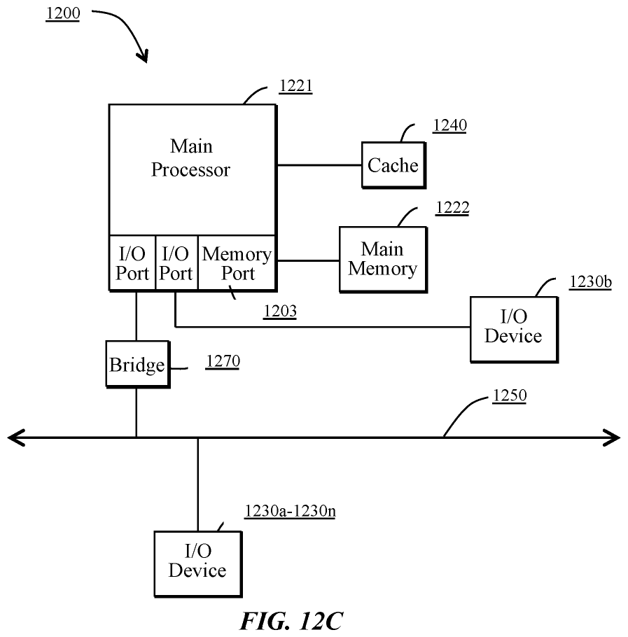

Having discussed specific embodiments of the present solution, it may be helpful to describe aspects of the operating environment as well as associated system components (e.g., hardware elements) in connection with the methods and systems described herein. Referring to FIG. 12A, an embodiment of a network environment is depicted. In brief overview, the network environment includes a wireless communication system that includes one or more access points 1206, one or more wireless communication devices 1202 and a network hardware component 1292. The wireless communication devices 1202 may for example include laptop computers 1202, tablets 1202, personal computers 1202 and/or cellular telephone devices 1202l The details of an embodiment of each wireless communication device and/or access point are described in greater detail with reference to FIGS. 12B and 12C. The network environment can be an ad hoc network environment, an infrastructure wireless network environment, a subnet environment, etc. in one embodiment

The access points (APs) 1206 may be operably coupled to the network hardware 1292 via local area network connections. The network hardware 1292, which may include a router, gateway, switch, bridge, modem, system controller, appliance, etc., may provide a local area network connection for the communication system. Each of the access points 1206 may have an associated antenna or an antenna array to communicate with the wireless communication devices 1202 in its area. The wireless communication devices 1202 may register with a particular access point 1206 to receive services from the communication system (e.g., via a SU-MIMO or MU-MIMO configuration). For direct connections (e.g., point-to-point communications), some wireless communication devices 1202 may communicate directly via an allocated channel and communications protocol. Some of the wireless communication devices 1202 may be mobile or relatively static with respect to the access point 1206.

In some embodiments an access point 1206 includes a device or module (including a combination of hardware and software) that allows wireless communication devices 1202 to connect to a wired network using Wi-Fi, or other standards. An access point 1206 may sometimes be referred to as an wireless access point (WAP). An access point 1206 may be configured, designed and/or built for operating in a wireless local area network (WLAN). An access point 1206 may connect to a router (e.g., via a wired network) as a standalone device in some embodiments. In other embodiments, an access point can be a component of a router. An access point 1206 can provide multiple devices 1202 access to a network. An access point 1206 may, for example, connect to a wired Ethernet connection and provide wireless connections using radio frequency links for other devices 1202 to utilize that wired connection. An access point 1206 may be built and/or configured to support a standard for sending and receiving data using one or more radio frequencies. Those standards, and the frequencies they use may be defined by the IEEE (e.g., IEEE 802.11 standards). An access point may be configured and/or used to support public Internet hotspots, and/or on an internal network to extend the network's Wi-Fi signal range.

In some embodiments, the access points 1206 may be used for (e.g., in-home or in-building) wireless networks (e.g., IEEE 802.11, Bluetooth, ZigBee, any other type of radio frequency based network protocol and/or variations thereof). Each of the wireless communication devices 1202 may include a built-in radio and/or is coupled to a radio. Such wireless communication devices 1202 and/or access points 1206 may operate in accordance with the various aspects of the disclosure as presented herein to enhance performance, reduce costs and/or size, and/or enhance broadband applications. Each wireless communication devices 1202 may have the capacity to function as a client node seeking access to resources (e.g., data, and connection to networked nodes such as servers) via one or more access points 1206.

The network connections may include any type and/or form of network and may include any of the following: a point-to-point network, a broadcast network, a telecommunications network, a data communication network, a computer network. The topology of the network may be a bus, star, or ring network topology. The network may be of any such network topology as known to those ordinarily skilled in the art capable of supporting the operations described herein. In some embodiments, different types of data may be transmitted via different protocols. In other embodiments, the same types of data may be transmitted via different protocols.

The communications device(s) 1202 and access point(s) 1206 may be deployed as and/or executed on any type and form of computing device, such as a computer, network device or appliance capable of communicating on any type and form of network and performing the operations described herein. FIGS. 12B and 12C depict block diagrams of a computing device 1200 useful for practicing an embodiment of the wireless communication devices 1202 or the access point 1206. As shown in FIGS. 12B and 12C, each computing device 1200 includes a central processing unit 1221, and a main memory unit 1222. As shown in FIG. 12B, a computing device 1200 may include a storage device 1228, an installation device 1216, a network interface 1218, an I/O controller 1223, display devices 1224a-1224n, a keyboard 1226 and a pointing device 1227, such as a mouse. The storage device 1228 may include, without limitation, an operating system and/or software. As shown in FIG. 12C, each computing device 1200 may also include additional optional elements, such as a memory port 1203, a bridge 1270, one or more input/output devices 1230a-1230n (generally referred to using reference numeral 1230), and a cache memory 1240 in communication with the central processing unit 1221.

The central processing unit 1221 is any logic circuitry that responds to and processes instructions fetched from the main memory unit 1222. In many embodiments, the central processing unit 1221 is provided by a microprocessor unit, such as: those manufactured by Intel Corporation of Mountain View, Calif.; those manufactured by International Business Machines of White Plains, N.Y.; or those manufactured by Advanced Micro Devices of Sunnyvale, Calif. The computing device 1200 may be based on any of these processors, or any other processor capable of operating as described herein.

Main memory unit 1222 may be one or more memory chips capable of storing data and allowing any storage location to be directly accessed by the microprocessor 1221, such as any type or variant of Static random access memory (SRAM), Dynamic random access memory (DRAM), Ferroelectric RAM (FRAM), NAND Flash, NOR Flash and Solid State Drives (SSD). The main memory 1222 may be based on any of the above described memory chips, or any other available memory chips capable of operating as described herein. In the embodiment shown in FIG. 12B, the processor 1221 communicates with main memory 1222 via a system bus 1250 (described in more detail below). FIG. 12C depicts an embodiment of a computing device 1200 in which the processor communicates directly with main memory 1222 via a memory port 1203. For example, in FIG. 12C the main memory 1222 may be DRDRAM.

FIG. 12C depicts an embodiment in which the main processor 1221 communicates directly with cache memory 1240 via a secondary bus, sometimes referred to as a backside bus. In other embodiments, the main processor 1221 communicates with cache memory 1240 using the system bus 1250. Cache memory 1240 typically has a faster response time than main memory 1222 and is provided by, for example, SRAM, BSRAM, or EDRAM. In the embodiment shown in FIG. 12C, the processor 1221 communicates with various I/O devices 1230 via a local system bus 1250. Various buses may be used to connect the central processing unit 1221 to any of the I/O devices 1230, for example, a VESA VL bus, an ISA bus, an EISA bus, a MicroChannel Architecture (MCA) bus, a PCI bus, a PCI-X bus, a PCI-Express bus, or a NuBus. For embodiments in which the I/O device is a video display 1224, the processor 1221 may use an Advanced Graphics Port (AGP) to communicate with the display 1224. FIG. 12C depicts an embodiment of a computer 1200 in which the main processor 1221 may communicate directly with I/O device 1230b, for example via HYPERTRANSPORT, RAPIDIO, or INFINIBAND communications technology. FIG. 12C also depicts an embodiment in which local busses and direct communication are mixed: the processor 1221 communicates with I/O device 1230a using a local interconnect bus while communicating with I/O device 1230b directly.

A wide variety of I/O devices 1230a-1230n may be present in the computing device 1200. Input devices include keyboards, mice, trackpads, trackballs, microphones, dials, touch pads, touch screen, and drawing tablets. Output devices include video displays, speakers, inkjet printers, laser printers, projectors and dye-sublimation printers. The I/O devices may be controlled by an I/O controller 1223 as shown in FIG. 12B. The I/O controller may control one or more I/O devices such as a keyboard 1226 and a pointing device 1227, e.g., a mouse or optical pen. Furthermore, an I/O device may also provide storage and/or an installation medium 1216 for the computing device 1200l In still other embodiments, the computing device 1200 may provide USB connections (not shown) to receive handheld USB storage devices such as the USB Flash Drive line of devices manufactured by Twintech Industry, Inc. of Los Alamitos, Calif.

Referring again to FIG. 12B, the computing device 1200 may support any suitable installation device 1216, such as a disk drive, a CD-ROM drive, a CD-R/RW drive, a DVD-ROM drive, a flash memory drive, tape drives of various formats, USB device, hard-drive, a network interface, or any other device suitable for installing software and programs. The computing device 1200 may further include a storage device, such as one or more hard disk drives or redundant arrays of independent disks, for storing an operating system and other related software, and for storing application software programs such as any program or software 1220 for implementing (e.g., configured and/or designed for) the systems and methods described herein. Optionally, any of the installation devices 1216 could also be used as the storage device. Additionally, the operating system and the software can be run from a bootable medium.

Furthermore, the computing device 1200 may include a network interface 1218 to interface to the network 1204 through a variety of connections including, but not limited to, standard telephone lines, LAN or WAN links (e.g., 802.11, T1, T3, 56 kb, X.25, SNA, DECNET), broadband connections (e.g., ISDN, Frame Relay, ATM, Gigabit Ethernet, Ethernet-over-SONET), wireless connections, or some combination of any or all of the above. Connections can be established using a variety of communication protocols (e.g., TCP/IP, IPX, SPX, NetBIOS, Ethernet, ARCNET, SONET, SDH, Fiber Distributed Data Interface (FDDI), RS232, IEEE 802.11, IEEE 802.11a, IEEE 802.11b, IEEE 802.11g, IEEE 802.11n, IEEE 802.11ac, IEEE 802.11ad, CDMA, GSM, WiMax and direct asynchronous connections). In one embodiment, the computing device 1200 communicates with other computing devices 1200′ via any type and/or form of gateway or tunneling protocol such as Secure Socket Layer (SSL) or Transport Layer Security (TLS). The network interface 1218 may include a built-in network adapter, network interface card, PCMCIA network card, card bus network adapter, wireless network adapter, USB network adapter, modem or any other device suitable for interfacing the computing device 1200 to any type of network capable of communication and performing the operations described herein.

In some embodiments, the computing device 1200 may include or be connected to one or more display devices 1224a-1224n. As such, any of the I/O devices 1230a-1230n and/or the I/O controller 1223 may include any type and/or form of suitable hardware, software, or combination of hardware and software to support, enable or provide for the connection and use of the display device(s) 1224a-1224n by the computing device 1200. For example, the computing device 1200 may include any type and/or form of video adapter, video card, driver, and/or library to interface, communicate, connect or otherwise use the display device(s) 1224a-1224n. In one embodiment, a video adapter may include multiple connectors to interface to the display device(s) 1224a-1224n. In other embodiments, the computing device 1200 may include multiple video adapters, with each video adapter connected to the display device(s) 1224a-1224n. In some embodiments, any portion of the operating system of the computing device 1200 may be configured for using multiple displays 1224a-1224n. One ordinarily skilled in the art will recognize and appreciate the various ways and embodiments that a computing device 1200 may be configured to have one or more display devices 1224a-1224n.

In further embodiments, an I/O device 1230 may be a bridge between the system bus 1250 and an external communication bus, such as a USB bus, an Apple Desktop Bus, an RS-232 serial connection, a SCSI bus, a FireWire bus, a FireWire 800 bus, an Ethernet bus, an AppleTalk bus, a Gigabit Ethernet bus, an Asynchronous Transfer Mode bus, a FibreChannel bus, a Serial Attached small computer system interface bus, a USB connection, or a HDMI bus.

A computing device 1200 of the sort depicted in FIGS. 12B and 12C may operate under the control of an operating system, which control scheduling of tasks and access to system resources. The computing device 1200 can be running any operating system such as any of the versions of the MICROSOFT WINDOWS operating systems, the different releases of the Unix and Linux operating systems, any version of the MAC OS for Macintosh computers, any embedded operating system, any real-time operating system, any open source operating system, any proprietary operating system, any operating systems for mobile computing devices, or any other operating system capable of running on the computing device and performing the operations described herein. Typical operating systems include, but are not limited to: Android, produced by Google Inc.; WINDOWS 7 and 8, produced by Microsoft Corporation of Redmond, Wash.; MAC OS, produced by Apple Computer of Cupertino, Calif.; WebOS, produced by Research In Motion (RIM); OS/2, produced by International Business Machines of Armonk, N.Y.; and Linux, a freely-available operating system distributed by Caldera Corp. of Salt Lake City, Utah, or any type and/or form of a Unix operating system, among others.

The computer system 1200 can be any workstation, telephone, desktop computer, laptop or notebook computer, server, handheld computer, mobile telephone or other portable telecommunications device, media playing device, a gaming system, mobile computing device, or any other type and/or form of computing, telecommunications or media device that is capable of communication. The computer system 1200 has sufficient processor power and memory capacity to perform the operations described herein.

In some embodiments, the computing device 1200 may have different processors, operating systems, and input devices consistent with the device. For example, in one embodiment, the computing device 1200 is a smart phone, mobile device, tablet or personal digital assistant. In still other embodiments, the computing device 1200 is an Android-based mobile device, an iPhone smart phone manufactured by Apple Computer of Cupertino, Calif., or a Blackberry or WebOS-based handheld device or smart phone, such as the devices manufactured by Research In Motion Limited. Moreover, the computing device 1200 can be any workstation, desktop computer, laptop or notebook computer, server, handheld computer, mobile telephone, any other computer, or other form of computing or telecommunications device that is capable of communication and that has sufficient processor power and memory capacity to perform the operations described herein.

Although the disclosure may reference one or more “users”, such “users” may refer to user-associated devices or stations (STAs), for example, consistent with the terms “user” and “multi-user” typically used in the context of a multi-user multiple-input and multiple-output (MU-MIMO) environment.

Although examples of communications systems described above may include devices and APs operating according to an 802.11 standard, it should be understood that embodiments of the systems and methods described can operate according to other standards and use wireless communications devices other than devices configured as devices and APs. For example, multiple-unit communication interfaces associated with cellular networks, satellite communications, vehicle communication networks, and other non-802.11 wireless networks can utilize the systems and methods described herein to achieve improved overall capacity and/or link quality without departing from the scope of the systems and methods described herein.

It should be noted that certain passages of this disclosure may reference terms such as “first” and “second” in connection with devices, mode of operation, transmit chains, antennas, etc., for purposes of identifying or differentiating one from another or from others. These terms are not intended to merely relate entities (e.g., a first device and a second device) temporally or according to a sequence, although in some cases, these entities may include such a relationship. Nor do these terms limit the number of possible entities (e.g., devices) that may operate within a system or environment.

It should be understood that the systems described above may provide multiple ones of any or each of those components and these components may be provided on either a standalone machine or, in some embodiments, on multiple machines in a distributed system. In addition, the systems and methods described above may be provided as one or more computer-readable programs or executable instructions embodied on or in one or more articles of manufacture. The article of manufacture may be a floppy disk, a hard disk, a CD-ROM, a flash memory card, a PROM, a RAM, a ROM, or a magnetic tape. In general, the computer-readable programs may be implemented in any programming language, such as LISP, PERL, C, C++, C#, PROLOG, or in any byte code language such as JAVA. The software programs or executable instructions may be stored on or in one or more articles of manufacture as object code.

While the foregoing written description of the methods and systems enables one of ordinary skill to make and use what is considered presently to be the best mode thereof, those of ordinary skill will understand and appreciate the existence of variations, combinations, and equivalents of the specific embodiment, method, and examples herein. The present methods and systems should therefore not be limited by the above described embodiments, methods, and examples, but by all embodiments and methods within the scope and spirit of the disclosure.

We claim:

1. A device, comprising:
a thin film bulk acoustic resonator (FBAR) circuit;
a phase-locked loop (PLL) circuit comprising a voltage controlled oscillator (VCO); and
a mixer circuit configured to receive the output signal from the FBAR circuit and an output signal from the VCO, and generate an intermodulation signal;
wherein the PLL circuit is further configured to receive the intermodulation signal as a second input.

2. The device of claim 1, further comprising a frequency divider circuit configured to receive an output signal from the VCO and provide a divided signal to the mixer circuit for mixing with the output signal from the FBAR circuit.

3. The device of claim 2, wherein the frequency divider circuit is an integer divider.

4. The device of claim 1, wherein the PLL circuit comprises a multiple modulus divider (MMD) configured to receive the output signal from the VCO.

5. The device of claim 1, wherein the mixer circuit comprises a sample and hold circuit.

6. The device of claim 1, wherein the mixer circuit comprises an XOR logic gate.

7. The device of claim 6, wherein the XOR logic gate is further configured to receive a frequency divided version of the output signal from the VCO.

8. The device of claim 1, wherein the PLL circuit comprises a frequency divider circuit; and
further comprising a compensation circuit configured to control a division ratio of the frequency divider circuit, responsive to a detection of frequency drift of the FBAR circuit.

9. A temperature compensating phase-locked loop (PLL) circuit, comprising:
a thin film bulk acoustic resonator (FBAR) circuit;
a time to data converter (TDC) circuit configured to interpolate an output signal from the FBAR circuit according to a reference frequency signal;
a loop filter configured to receive the TDC output signal and generate a signal representing a frequency error of the FBAR circuit; and
a temperature compensation loop circuit, configured to receive the frequency error signal from the loop filter and generate a control signal for the FBAR circuit.

10. The PLL circuit of claim 9, wherein the temperature compensation loop circuit further comprises an amplifier configured to receive the frequency error signal from the loop filter and generate a gain adjusted frequency error signal.

11. The PLL circuit of claim 10, wherein the temperature compensation loop circuit further comprises an adaptive gain control circuit configured to monitor the frequency error signal from the loop filter and control gain of the amplifier, responsive to the monitoring.

12. The PLL circuit of claim 11, wherein the adaptive gain control circuit is configured to increase gain of the amplifier responsive to determining that the frequency error signal exceeds a threshold.

13. The PLL circuit of claim 11, wherein the temperature compensation loop circuit further comprises an adjustable bandwidth filter.

14. The PLL circuit of claim 13, wherein the adaptive gain control circuit is further configured to increase bandwidth of the adjustable bandwidth filter, responsive to determining that the frequency error signal exceeds a threshold.

15. A multi-phase phase-locked loop (PLL) circuit comprising:
an oscillator;
a multi-phase divider receiving an output of the oscillator and comprising a plurality of frequency divided outputs, each frequency divided output of the multi-phase divider having a corresponding phase offset;
a corresponding plurality of detectors, each detector receiving a corresponding frequency divided output of the multi-phase divider and an input reference signal and configured to generate a difference signal representative of a difference between the corresponding frequency divided output and the input reference signal; and
a combiner in communication with each of the plurality of detectors configured to generate a single combined output of the plurality of generated difference signals, the single combined output controlling a frequency of the oscillator.

16. The multi-phase PLL circuit of claim 15, further comprising a compensation circuit receiving the output of the oscillator and providing a compensated output to the multi-phase divider.

17. The multi-phase PLL circuit of claim 16, wherein the compensation circuit comprises a delta-sigma modulator in parallel with a multiple modulus divider.

18. The multi-phase PLL circuit of claim 15, wherein each detector comprises an XOR logic gate.

19. The multi-phase PLL circuit of claim 15, wherein each detector comprises an edge-triggered logic circuit.

20. The multi-phase PLL circuit of claim 15, further comprising a plurality of notch filters tuned to a harmonic of the input reference signal, each receiving an output of a corresponding detector of the plurality of detectors.
